(19) United States
(12) Patent Application Publication
(10) Pub. No.: US 2025/0309048 A1
(43) Pub. Date: Oct. 2, 2025

(54) POROUS METAL LAYERS AND METHODS FOR MAKING POROUS METAL LAYERS

(71) Applicants: Toyota Motor Engineering & Manufacturing North America, Inc., Plano, TX (US); The Board of Trustees of the University of Illinois, Urbana, IL (US)

(72) Inventors: Sujan Dewanjee, Urbana, IL (US); Gaurav Singhal, Champaign, IL (US); Nenad Miljkovic, Urbana, IL (US); Paul Vannest Braun, Champaign, IL (US); Shailesh N. Joshi, Ann Arbor, MI (US); Danny J. Lohan, West Bloomfield, MI (US)

(73) Assignees: Toyota Motor Engineering & Manufacturing North America, Inc., Plano, TX (US); The Board of Trustees of the University of Illinois, Urbana, IL (US)

(21) Appl. No.: 18/624,731

(22) Filed: Apr. 2, 2024

(51) Int. Cl. H01L 23/473; H01L 21/48

(52) U.S. Cl. CPC H01L 23/473; H01L 21/4871

(57) ABSTRACT

A porous metal structure includes a substrate, and a porous metal layer bonded to the substrate. The porous metal layer is a low temperature sintered metal-metal formate slurry layer with less than 10% by volume of excess reduced metal formate and has an outer surface with an arithmetical mean height less than about 10 μm.

### TECHNICAL FIELD

The present disclosure relates to porous layers, and particularly to porous metal layers.

### BACKGROUND

Heat generating devices, such as power semiconductor devices, may be coupled to a cold plate to remove heat and lower the maximum operating temperature of the heat generating device. In some applications, cooling fluid may be used to receive heat generated by the heat generating device by convective thermal transfer from a heat transfer surface, and remove such heat from the heat generating device. Also, porous metal layers have been proposed to enhance heat transfer from heat generating devices. However, fabrication of porous metal layers and bonding of such layers to heat transfer surfaces may be difficult and/or result in damage of the heat generating device.

The present disclosure addresses issues related to the manufacture of porous metal layers and other issues related to porous metal layers.

### SUMMARY

This section provides a general summary of the disclosure and is not a comprehensive disclosure of its full scope or all of its features.

In one form of the present disclosure, a porous metal structure includes a substrate and a porous metal layer bonded to the substrate. The porous metal layer includes a low temperature sintered metal-metal formate slurry layer with less than 10% by volume excess reduced metal formate.

In another form of the present disclosure, a porous metal structure includes a substrate and a porous copper layer bonded to the substrate. The porous copper layer includes a low temperature sintered copper-copper formate slurry layer with less than 10% by volume of excess reduced copper formate and an outer surface with an arithmetical mean height less than about 10 μm.

In still another form of the present disclosure, a porous metal structure includes a semiconductor substrate, a copper layer bonded to the semiconductor substrate, and a porous copper layer bonded to the substrate. The porous copper layer includes a low temperature sintered copper-copper formate slurry layer with less than 10% by volume of excess reduced copper formate and an outer surface with an arithmetical mean height less than about 10 μm.

Further areas of applicability and various methods of enhancing the above technology will become apparent from the description provided herein. The description and specific examples in this summary are intended for purposes of illustration only and are not intended to limit the scope of the present disclosure.

### BRIEF DESCRIPTION OF THE DRAWINGS

The present teachings will become more fully understood from the detailed description and the accompanying drawings, wherein:

FIG. 1 is a flow chart for a method of forming a porous metal layer according to the teachings of the present disclosure;

FIG. 2A is a scanning electron microscope (SEM) image of a porous metal layer;

FIG. 2B is a scanning electron microscope (SEM) image of a porous metal layer formed according to the teachings of the present disclosure;

FIG. 3 is a scanning electron microscope (SEM) image of another porous metal layer formed according to the teachings of the present disclosure and using the same materials used to from the porous metal layer in FIG. 2A;

FIG. 4 is a perspective view of a silicon wafer bonded to another silicon wafer with a porous metal layer formed according to the teachings of the present disclosure;

FIG. 5 is a perspective view of a porous metal layer formed according to the teachings of the present disclosure bonded to a glass tube;

FIG. 6 illustrates a cooling apparatus with a porous metal layer according to the teachings of the present disclosure;

FIG. 6A is an enlarged view of section 6A in FIG. 6; and

FIG. 7 illustrates a power electronics assembly with a porous metal layer according to the teachings of the present disclosure.

It should be noted that the figures set forth herein are intended to exemplify the general characteristics of the methods, devices, and systems among those of the present technology, for the purpose of the description of certain aspects. The figures may not precisely reflect the characteristics of any given aspect and are not necessarily intended to define or limit specific forms or variations within the scope of this technology.

### DETAILED DESCRIPTION

The present disclosure provides porous metal layers and methods for forming porous metal layers. The porous metal layers are formed by sintering a slurry layer that includes metal particles and metal formate. That is, the porous metal layers are sintered metal particle-metal formate slurry layers (also referred to herein simply as “metal-metal formate slurry layers(s)”), where the term “sinter” or “sintered” as used herein refers to heating a slurry layer with metal particles mixed with a metal formate-solvent solution such that the metal formate chemically reduces and forms bonds between the metal particles without the metal particles melting. In some variations, the sintered metal-metal formate slurry layers are sintered without pressure, other than atmospheric pressure, applied to the metal-metal formate slurry layers during sintering thereof.

The metal particles in the sintered slurry layer can be selected in order to provide a porous metal layer with a desired porosity, desired value of heat transfer and/or desired value of electrical conductivity. For example, the metal particles can be copper particles, copper alloy particles, aluminum particles, or aluminum alloy particles, among others. Also, the metal particles can be micron-size particles with have an average diameter between about 100 nanometers (nm) and about 500 micrometers (μm). In some variations, the metal particles have an average diameter between about 100 nm and about 200 nm, between about 200 nm and about 300 nm, between about 300 nm and about 400 nm, between about 400 nm and about 500 nm, between about 500 nm and about 600 nm, between about 600 nm and about 700 nm, between about 700 nm and about 800 nm, between about 800 nm and about 900 nm, between about 900 nm and about 1000 nm, between about 1000 nm and about 10 μm, between about 10 μm and 50 μm, between about 50 μm and 100 μm, between about 100 μm and 150 μm, between about 150 μm and 200 μm, between about 200 μm and 250 μm, between about 250 μm and 300 μm, between about 300 μm and 350 μm, between about 350 μm and 400 μm, between about 400 μm and 450 μm, and/or between about 450 μm and 500 μm.

The slurry is synthesized such that a uniform sintered metal-metal formate slurry layer is provided. And as used herein, the phrase “uniform sintered metal-metal formate slurry layer” refers to sintered metal-metal formate slurry layer without a delaminated layer of excess reduced metal formate. Accordingly, the porous metal layers according to the teachings of the present disclosure have a generally uniform and smooth outer surface and a generally uniform particle packing density. In some variations, the slurry is synthesized such that the amount of metal formate in the slurry is carefully controlled, e.g., reduced, such that sufficient metal formate is present for sintering of the metal particles together and yet excess metal formate is not present to form delaminated layers of reduced metal formate in or on a sintered metal-metal formate slurry layer.

In some variations, the metal-metal formate slurry is sintered at low temperatures to form a porous metal layer. Stated differently, porous copper layers according to the teachings of the present disclosure are low-temperature sintered porous metal layers. As used herein, the phrase “low-temperature sintered” refers to a temperature used to form a sintered metal-metal formate slurry layer according to the teachings of the present disclosure that it is at least 100° C. less than a temperature used to sinter the same metal particles according to traditional sintering techniques. Accordingly, the porous metal layers according to the teachings of the present disclosure can be sintered at temperatures that are lower than traditional sintering temperatures for known porous metal layers. For example, slurries formed from copper particles and copper formate are traditionally sintered at temperatures equal to or greater than 400° C. and such high sintering temperatures can damage substrates of heat generating devices and/or heat generating devices to which such a porous copper layer is sintered (bonded) to. For example, sintering temperatures of 400° C. and above can damage a semiconductor device to which a porous copper layer is sintered to.

A predefined thickness of a porous metal layer according to the teachings of the present disclosure can range from a few micrometers thick to several hundred micrometers. For example, an average thickness of a low temperature sintered copper-copper formate slurry layer can be between about 1 μm and about 500 μm. In some variations, an average thickness of a low temperature sintered copper-copper formate slurry layer is between about 10 μm and about 30 μm, between about 30 μm and about 50 μm, between about 50 μm and about 75 μm, between about 75 μm and about 100 μm, between about 100 μm and about 150 μm, between about 150 μm and about 200 μm, between about 200 μm and about 250 μm, between about 250 μm and about 300 μm, between about 300 μm and about 350 μm, between about 350 μm and about 400 μm, between about 400 μm and about 450 μm, and/or between about 450 μm and about 500 μm.

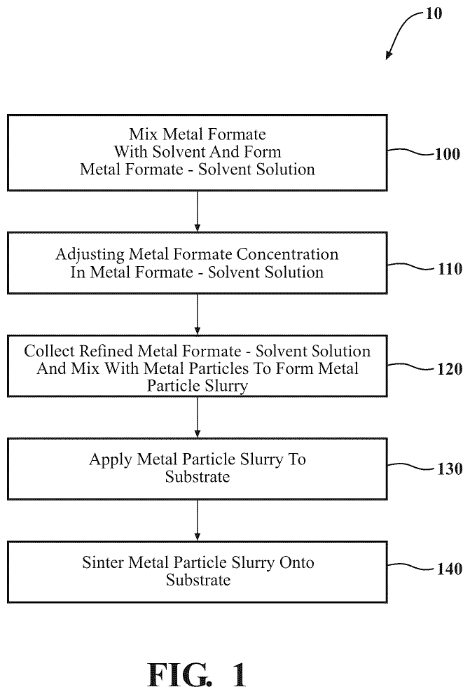

Referring to FIG. 1, a method 10 for forming a porous metal layer is shown. The method 10 includes mixing a metal formate with a solvent to form a metal formate-solvent solution at 100, and adjusting the content (concentration) of the metal formate in the metal formate-solvent solution at 110 to form a refined metal formate-solvent solution.

As used herein, the phrase “refined metal formate-solvent solution” refers to a metal formate-solvent solution a concentration of metal formate such that low temperature sintering of a slurry layer formed from a plurality of metal particles mixed with the refined metal formate-solvent solution results in a sintered metal-metal formate slurry layer with less than 10 percent by volume excess reduced metal formate. And as used herein, the phrase “excess reduced metal formate” refers to reduced metal formate in a sintered metal-metal formate slurry layer that is not between and bonded to adjacent metal particles and the phrase “percent by volume” is a comparison of the volume of excess reduced metal formate to the volume of metal particles in a given sintered metal-metal formate layer. For example, in some variations, a refined metal formate-solvent solution results in less than 5% by volume excess reduced copper formate sintered metal-metal formate slurry layer formed therefrom. And in some variations, a sintered metal-metal formate slurry layer according to the teachings of the present disclosure has less than 2% by volume excess reduced metal formate, e.g., less than 1% by volume of excess reduced copper formate.

In some variations, the concentration of metal formate in the metal formate-solvent solution is reduced, e.g., using a filtering technique such as vacuum filtration, centrifugal filtration, gravity filtration, centrifugal filtration, granular filtration, mechanical filtration, and/or multilayer filtration, among others. Non-limiting examples of the metal formate include copper formate (C₂H₂CuO₄), iron formate (C₂H₈FeO₆), silver formate (CHAgO₂), and aluminum formate (Al(HCOO)₃), among others, and non-limiting examples of the solvent include isopropanolamine, cyclohexylamine, n-octyl amine, among others.

The refined metal formate-solvent solution is collected and mixed with metal particles to form a metal particle slurry at 120. The metal particle slurry is applied to a substrate at 130 and the metal particle slurry is sintered onto the substrate at 140. Non-limiting examples of the metal particles include copper particles, copper alloy particles, iron particles, iron alloy particles, silver particles, silver alloy particles, aluminum particles, and aluminum alloy particles, among others. And non-limiting examples of the substrate can include substrates formed from semiconductor materials, metals, alloys, polymers, ceramics, and glass, among others.

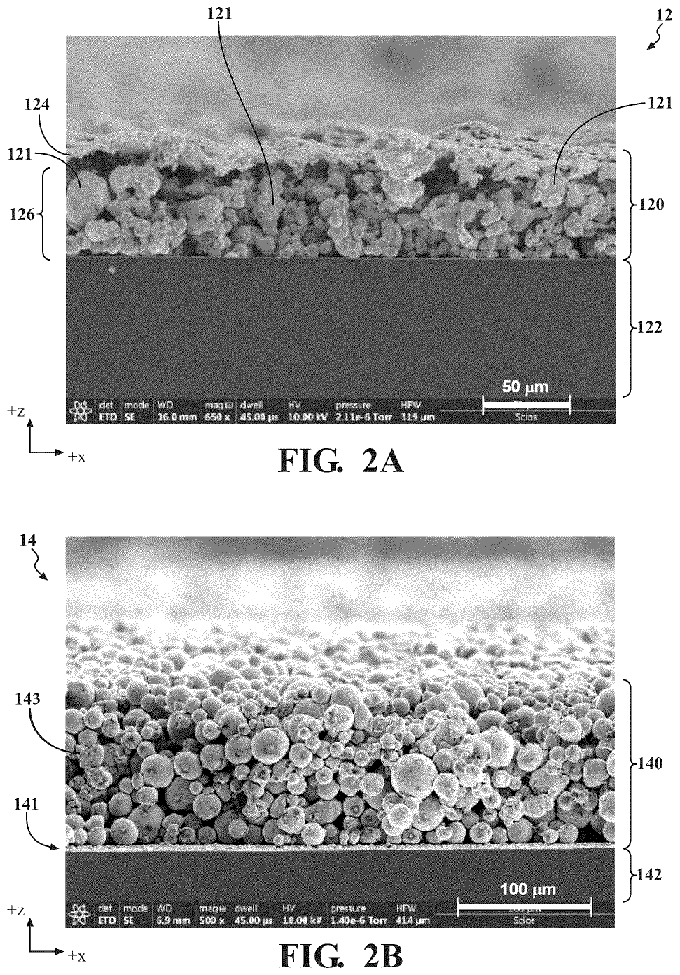

Referring to FIGS. 2A-2B, a porous copper layer 12 formed without using a refined copper formate-solvent solution as described above is shown in FIG. 2A and a porous copper layer 14 formed with using a refined copper formate-solvent solution according to teachings of the present disclosure is shown in FIG. 2B. The porous copper layer 12 includes a sintered copper-copper formate slurry layer 120 on a substrate 122 in the form of a gold coated silicon wafer and the porous copper layer 14 includes a sintered copper-copper formate slurry layer 140 sintered onto an interface layer 141 on a substrate 142 in the form of a gold coated silicon wafer. It should be understood that the sintered copper-copper formate slurry layer 140 can be sintered directly onto the substrate 142, i.e., the interface layer 141 is not required.

As observed in FIG. 2A, the sintered copper-copper formate slurry layer 120 includes clusters or globs (i.e., accumulations) 121 of copper formate and an upper layer 124 of copper formate is delaminated (separated) from an underlying layer 126 of sintered copper particles. Accordingly, it should be understood that the sintered copper-copper formate slurry layer 120 is generally non-uniform with an uneven distribution of copper particles, a large variation in pore size between the copper particles, and a rough outer (+z direction) surface as discussed in greater detail below.

In contrast, the sintered copper-copper formate slurry layer 140 shown in FIG. 2B does an upper (+z direction) delaminated layer of copper formate separated from an underlying (−z direction) layer of sintered copper particles and has only a small amount (less than 10% by volume) of excess reduced copper formate 143. Accordingly, it should be understood that the sintered copper-copper formate slurry layer 140 is generally uniform with an even distribution of copper particles, a small variation in pore size between the copper particles, and a smooth outer (+z direction) surface as discussed in greater detail below. In some variations, and as observed from FIG. 2B, the sintered copper-copper formate slurry layer 140 has less than 10% by volume excess reduced copper formate 143, e.g., less than 5% by volume excess reduced copper formate 143. And in some variations, the sintered copper-copper formate slurry layer 140 has less than 2% by volume excess reduced copper formate 143, e.g., less than 1% by volume excess reduced copper formate 143.

The sintered copper-copper formate slurry layer 140 was formed from a copper-copper formate slurry that was synthesized by mixing copper formate powder with isopropanolamine at a 1:6 weight ratio to form a copper formate-solvent solution. The copper formate-solvent solution was subjected to vacuum filtration through a filter with an average pore diameter of 100 μm to form a refined copper formate-solvent solution. And the refined copper formate-solvent solution was mixed with copper particles having an average particle diameter between about 10 μm and 20 μm to form a copper-copper formate slurry. The copper-copper formate slurry was then applied to the substrate 142 (i.e., to the interface layer 141) using a doctor blade to form a copper-copper formate slurry layer. The copper-copper formate slurry layer was heated in the range between 100° C. and 120° C. for 1 hour for solvent evaporation and then at 150° C. for 2 hours in a tube furnace with flowing argon (or nitrogen) to reduce the copper formate to copper and form bonds between adjacent copper particles. And while the copper-copper formate slurry layer was applied to the substrate 142 using a doctor blade, the copper-copper formate slurry layer can also be applied using other techniques such as additive manufacturing (3D printing), molding, casting, extrusion, among others.

Still referring to FIG. 2B, in some variations, the bonding interface layer 141 is included to enhance the bonding strength between the sintered copper-copper formate slurry layer 140 and the substrate 142. And while the bonding interface layer 141 shown in FIG. 2B was applied via an electrodeposition technique, other techniques can be used to apply or form the bonding interface layer 141 on the substrate such as physical vapor deposition (PVD) techniques, chemical vapor deposition (CVD) techniques, among others.

Referring back to FIG. 2A, the outer (+z direction) surface of the sintered copper-copper formate slurry layer 120 was subjected to a surface area roughness analysis with a Keyence VK-X1000 3D laser Scanning Confocal Microscope and the results of the analysis are provided in Table 1 below.

TABLE 1

| Measurement | Value | |
|---|---|---|
| Sa (Arithmetical Mean Height) | 77.1 | μm |
| Sz (Maximum Height) | 427.0 | μm |
| Sq (Root Mean Square Height) | 90.6 | μm |
| Ssk (Skewness) | −0.3 | |
| Sp (Maximum Peak Height) | 185.7 | μm |
| Sv (Maximum Peak Height) | 241.3 | μm |

As used herein, the measurement “Sa” is an extension of Ra (i.e., the arithmetical mean height of a line across a surface) for a surface, is generally used to evaluate surface roughness, and expresses, as an absolute value, the difference in height of each point compared to the arithmetical mean of the surface. The measurement “Sz” is defined as the sum of the largest peak height value and the largest pit depth value within a defined area. The measurement “Sq” is defined as the root mean square value of ordinate values within a defined area and equivalent to the standard deviation of heights. The measurement “Ssk” represents the degree of bias of the roughness shape (asperity) with Ssk values less than zero (i.e., Ssk<0) describing a height distribution skewed above the mean plane of a surface, Ssk values equal to zero (i.e., Ssk=0) describing a height distribution (peaks and pits) symmetrical about the mean plane of a surface, and Ssk values greater than zero (i.e., Ssk>0) describing a height distribution skewed below the mean plane of a surface. The measurement “Sp” represents the height of the highest peak of a surface of a predefined surface area and the measurement “Sv” represents the depth of the lowest peak of a surface of a predefined surface area.

And referring particularly to FIG. 2B, the upper (+z direction) surface of the sintered copper-copper formate slurry layer 140 was also subjected to a surface area roughness analysis with the Keyence VK-X1000 3D laser Scanning Confocal Microscope and the results of the analysis are provided in Table 2 below.

TABLE 2

| Measurement | Value | |
|---|---|---|
| Sa (Arithmetical Mean Height) | 6.5 | μm |
| Sz (Maximum Height) | 119.8 | μm |
| Sq (Root Mean Square Height) | 8.4 | μm |
| Ssk (Skewness) | 0.015 | |
| Sp (Maximum Peak Height) | 60.1 | μm |
| Sv (Maximum Pit Depth) | 59.6 | μm |

As observed from Tables 1 and 2, the sintered copper-copper formate slurry layer 140 exhibits a significantly smoother (less rough) and more uniform outer surface than the sintered copper-copper formate slurry layer 120. For example, the surface roughness of the sintered copper-copper formate slurry layer 140 as expressed by “Sa” is more than an order of magnitude (11.9) less than the surface roughness of the sintered copper-copper formate slurry layer 120, the degree of bias of the roughness shape (asperity) for the sintered copper-copper formate slurry layer 140, as expressed by “Ssk”, is twenty (20) times less than the asperity for the sintered copper-copper formate slurry layer 120, and the maximum peak and maximum pit depth for the sintered copper-copper formate slurry layer 140, as represented by “Sp” and “Sv”, respectively, are about 3 times and 4 times, respectively, less than the maximum peak and maximum pit depth for the sintered copper-copper formate slurry layer 140. In addition, and as observed form comparing FIG. 2B to FIG. 2A, the uniformity of the outer surface of the sintered copper-copper formate slurry layer 140 translates to the distribution of copper particles within the sintered copper-copper formate slurry layer 140. Stated differently, the use of a refined metal formate-solvent solution as described above reduces or eliminates excess metal formate in a resulting sintered metal-metal formate slurry layer and thereby provides a more uniform porous metal layer that can be used for heat extraction from heat generating devices.

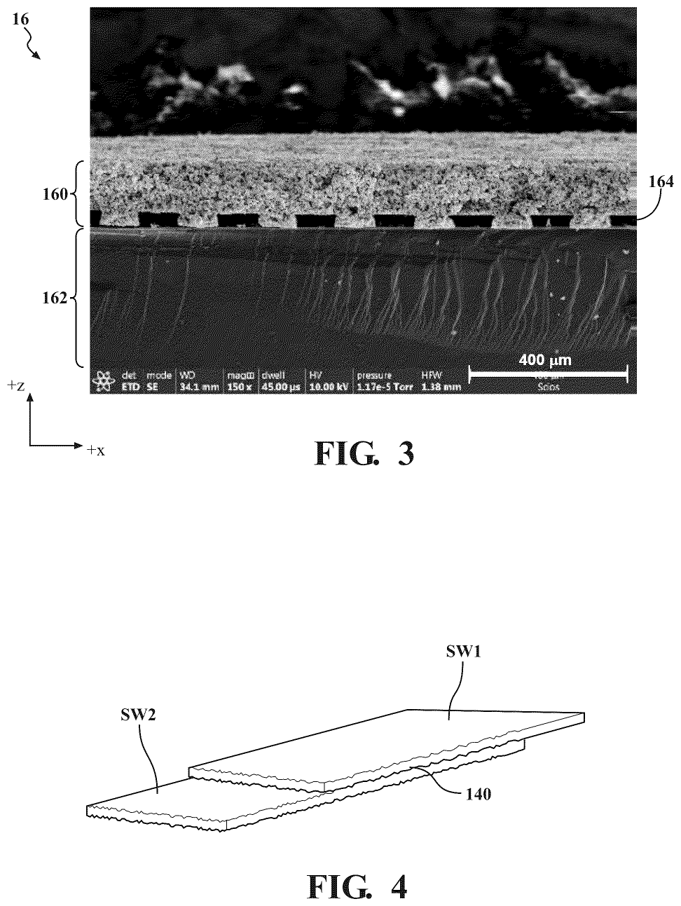

Referring to FIG. 3, another porous copper layer 16 formed according to teachings of the present disclosure is shown. The porous copper layer 16 includes a sintered copper-copper formate slurry layer 160, with microchannels 164, on a substrate 162. It should be understood that the uniformity of the sintered copper-copper formate slurry layer 160 allows for the formation of such intricate small-dimensioned features (i.e., the microchannels 164) to be formed. Stated differently, the reduction or absence of excess copper formate in the refined copper formate-solvent solution used to form the sintered copper-copper formate slurry layer 160 results in uniform copper particle distribution within the porous copper layer 16, porous copper layer with a smooth outer (+z direction) surface as observed from FIG. 3, and allows for desired small (tens of micrometers) features with distinct and generally smooth walls or surfaces to be formed in the sintered copper-copper formate slurry layer 160. In some variations, additive manufacturing (3D printing) is used to form the copper-copper formate slurry layer 160 with the microchannels 164 on the substrate 162 before sintering, while in other variations, the copper-copper formate slurry layer 160 is applied to the substrate using a doctor blade. In such variations, inserts, e.g., paraffin inserts, that melt and dissipate during the sintering process are used to form the microchannels 164.

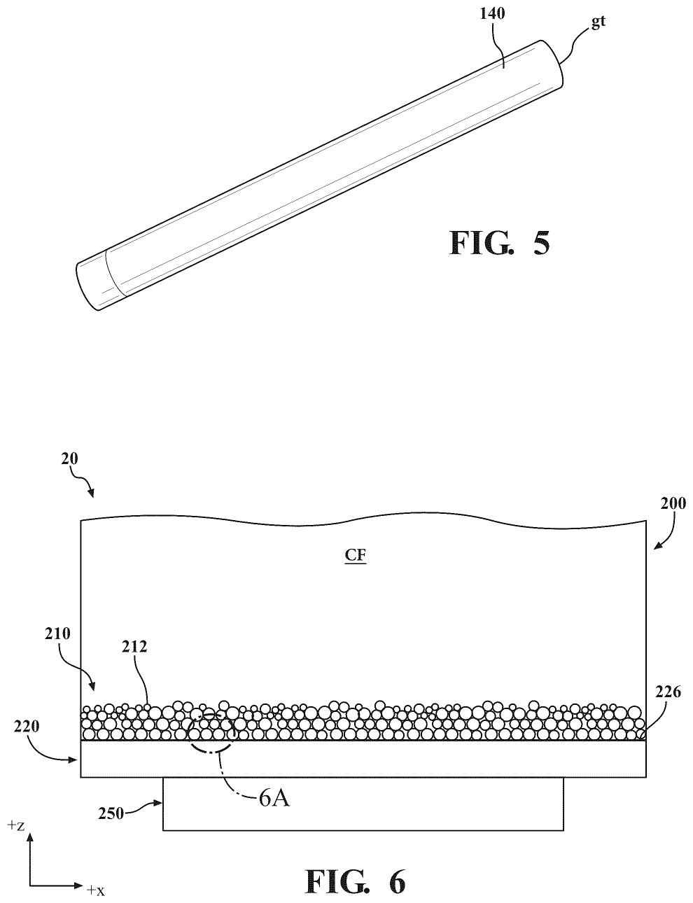

Referring to FIG. 4, a pair of silicon wafers SW1, SW2 bonded together by the sintered copper-copper formate slurry layer 140 is shown. Accordingly, it should be understood that porous metal layers according to the teachings of the present disclosure can be used to bond two or more components together. And with reference to FIG. 5, a sintered copper-copper formate slurry layer 140 formed on or within, and bonded to, a glass tube ‘gt’ is shown. Also, the sintered copper-copper formate slurry layer 140 is electrically conducting and thus can be used as a heater for the glass tube gt.

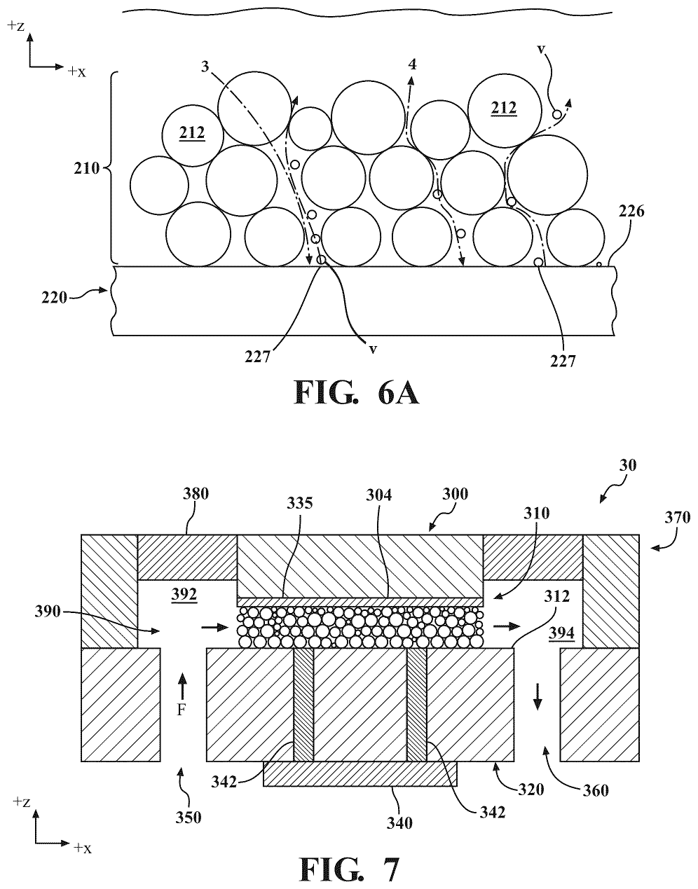

Referring to FIGS. 6 and 6A, a power electronics module 20 with a cooling apparatus 200 coupled to a substrate 220 (e.g., a cooling substrate) and a semiconductor device 250 is shown. Semiconductor devices may include, but are not limited to, insulated gate bipolar transistors (IGBT), metal-oxide-semiconductor field effect transistors (MOSFET), power diodes, power bipolar transistors, power thyristor devices, and the like. As an example and not a limitation, the semiconductor device may be included in a power electronic module as a component in an inverter and/or converter circuit used to electrically power high load devices, such as electric motors in electrified vehicles (e.g., hybrid vehicles, plug-in hybrid electric vehicles, plug-in electric vehicles, and the like). The cooling apparatuses described herein may also be used to cool heat generating devices other than semiconductor devices (e.g., mechanical devices, such as motors).

As shown in FIG. 6, a porous metal layer 210 according to the teachings of the present disclosure is thermally coupled and bonded to the substrate 220, which may or may not be part of the cooling apparatus 200. The cooling apparatus 200 includes the porous metal layer 210 sintered at low temperatures to a beat transfer surface 226 of the substrate 220 and cooling fluid ‘CF’ is in contact with the porous metal layer 210. The porous metal layer 210 includes a plurality of metal particles 212, e.g., copper particles sintered together at temperatures less than 200° C. In some variations, the porous metal layer 210 is formed separate from the cooling apparatus 200, positioned adjacent to and in contact with the substrate 220, and then bonded to the heat transfer surface 226. In other variations, the porous metal layer 210 is formed in place, i.e., a metal-metal formate slurry layer according to the teachings of the present disclosure is formed on the heat transfer surface 226 and then sintered to form the porous metal layer 210 bonded to the heat transfer surface 226. And while not shown it should be understood that the porous metal layer 210 can be formed directly on the semiconductor device 250 (with or without an interface layer) and/or that desired small (tens of micrometers) features with distinct and generally smooth walls or surfaces as described above with respect to FIG. 3 can be formed within the porous metal layer 210.

Referring now to FIG. 6A, an enlarged view of section 6A in FIG. 6 is shown. The porous metal layer 210 is formed from the plurality of metal particles 212 with porosity formed by pores, micro-channels, gaps between adjacent metal particles 212. Depending on the size (diameter) of the metal particles, porosity within the porous metal layer 210 may be greater than 10 volume percent (vol %), greater than 20 vol %, greater than 30 vol %, greater than 40 vol %, or greater than 50 vol %, and less than 90 vol %, less than 80 vol %, less than 70 vol %, less than 60 vol %, less than 50 vol %, less than 40 vol %, or less than 30 vol %. In some variations, the porosity within the porous metal layer 210 is between about 10 vol % and about 90 vol %, for example between about 30 vol % and about 70 vol %. In some embodiments, the porosity within the porous metal foam layer is between about 30 vol % and about 70 vol %, for example between about 40 vol % and about 60 vol %.

The porous metal layer 210 also includes micro-channels extending from an outer (+z direction) surface of the porous metal layer 210 to the heat transfer surface 226 as depicted by the arrows ‘3’ and ‘4’ in FIG. 6A. The micro-channels 3, 4 provide a path for a cooling fluid CF to flow from the outer surface of the porous metal layer 210 to the heat transfer surface 226. In at least one variation, the micro-channels 3, 4 wick the cooling fluid from the outer surface of the porous metal layer 210 to the heat transfer surface 226 thereby enhancing the flow of the cooling fluid CF to the heat transfer surface 226. In some variations, the micro-channels have an average diameter between 5 μm and 1,000 μm. For example, the micro-channels may have an average diameter greater than 5 μm, greater than 10 μm, greater than 15 μm, greater than 20 μm, greater than 30 μm, greater than 40 μm, greater than 50 μm, greater than 75 μm, greater than 100 μm, or greater than 200 μm, and less than 1,000 μm, less than 750 μm, less than 500 μm, less than 250 μm, less than 150 μm, less than 100 μm, less than 75 μm or less than 50 μm. In some embodiments, the micro-channels have an average diameter between about 25 μm and about 200 μm, for example between about 40 μm and about 120 μm. In other embodiments, the micro-channels have an average diameter between about 40 μm and 150 μm, for example between about 50 μm and about 100 μm.

The heat transfer surface 226 may have a plurality of micro-boiling nucleation sites 227 between adjacent metal particles 212. That is, areas between adjacent metal particles 212 sintered to the heat transfer surface 226 provide nucleation sites for boiling of the cooling fluid CF. Accordingly, the porous metal layer 210 sintered to the substrate 220 enhances micro-boiling at the heat transfer surface 226 with vapor bubbles ‘v’ formed and flowing out towards the outer surface of the porous metal layer 210 through the micro-channels 3, 4 depicted in FIG. 6A.

The porous metal layer 210 enhances convective heat flow from the heat transfer surface 226. Particularly, the gaps, spaces, pores, etc., provide for the micro-channels 3, 4 extending from the outer surface to the heat transfer surface 226. The micro-channels 3, 4 comprise an average inner diameter such that capillary action is exerted on the cooling fluid CF and the CF is wicked to the heat transfer surface 226. The micro-channels 3, 4 provide passageways for the vapor v to flow from the heat transfer surface 226 to the outer surface of the porous metal layer 210 (flow boiling) in addition, flow boiling through micro-channels can provide high heat transfer rates compared to boiling in conventional heat exchangers.

In addition to providing heat removal layers as discussed above, and as noted above, the continuous metal particle-to-metal particle contact throughout the porous metal layers according to the teachings of the present disclosure provide electrically conductive layers. For example, and with reference to FIG. 7, a power electronics assembly 30 with a porous metal layer 310 is shown. The power electronics assembly 30 generally includes a semiconductor device 300 with a bottom surface 304 and a substrate 320 with a top surface 312. The porous metal layer 310 is positioned between and bonded to the semiconductor device 300 and the substrate 320. In some variations, an electrode 335 is disposed (sandwiched) between the bottom surface 304 of the semiconductor device 300 and the top surface 312 of the substrate 320, and in such variations, the porous metal layer 310 can be sintered to the electrode 335 and the substrate 320. In other variations, the electrode 335 is not present between the bottom surface 304 of the semiconductor device 300 and the top surface 312 of the substrate 320, and in such variations, the porous metal layer 310 can be sintered directly to the bottom surface 304 of the semiconductor device 300 and the substrate 320. While not shown in FIG. 7, it should be understood that one or more bonding layers (not shown) can be disposed between the porous metal layer 310 and the electrode 335 and/or between the porous metal layer 310 and the top surface 312 of the substrate 320.

In some variations, one or more electrically conductive through vias 342 extend through (z-direction) the substrate 320 and are in electrical contact with the electrode 335. And in such variations, the porous metal layer functions as an electrically conductive path between the electrode 335 and another electrode 340.

A frame 370 may be disposed on the top surface 312 of the substrate 320 and the semiconductor device 300 may be disposed at least partially within the frame 370. That is, the frame 370 may be spaced apart from and extend around at least a portion of the semiconductor device 300. And while FIG. 7 depicts the substrate 320 and the frame 370 as separate components, it should be appreciated that the substrate 320 and the frame 370 may be formed as a single component to house the semiconductor device 300.

As noted above, the porous metal layer 310 has a plurality of metal particles 325. In addition, the size(s) of the metal particles, the particle packing density, and the porosity provide a stiffness and a thermal conductivity for the porous metal layer 310. That is, a stiffness and a thermal conductivity for the porous metal layer 310 are a function of the metal particle size(s), particle packing density, and porosity of the porous metal layer 310, and as such, a desired stiffness and/or thermal conductivity can be engineered by choosing the appropriate particle size(s) in order to arrive at or obtain a desired spherical packing density and porosity. As used herein, the term stiffness refers to the elastic modulus (also known as Young's modulus) of a material, i.e., a measure of a material's resistance to being deformed elastically when a force is applied to the material. And the stiffness and the thermal conductivity of the porous metal layer 310 can be varied and controlled to accommodate thermal stress for a given semiconductor device 300-substrate 320 combination and/or provided a desired heat removal rate for a given semiconductor device 300-substrate 320 combination.

The porous metal layer 310 has an open porous structure and can be part of a cooling fluid circuit for the power electronics assembly 30. For example, in some variations a cooling fluid circuit (not labeled) includes a cooling fluid inlet 350 through the substrate 320, an internal cooling fluid chamber 390, and a cooling fluid outlet 360 extending through the substrate 320. The internal cooling fluid chamber 390 includes an inlet cooling chamber 392, the porous metal layer 310, and an outlet cooling chamber 394. As depicted by the arrows in FIG. 7, a cooling fluid ‘F’ may be included and flow into the power electronics assembly 30 through the cooling fluid inlet 350. The frame 370 and at least one seal 380 prevent the cooling fluid F from flowing up (+z direction) past the semiconductor device 300 and thereby ensuring the cooling fluid F flows through the porous metal layer 310, into the outlet cooling chamber 394, and through the cooling fluid outlet 360. It should be understood that flow of the cooling fluid F through the cooling fluid circuit removes heat from the semiconductor device 300. Non-limiting examples of the cooling fluid CF include dielectric cooling fluids such as aromatics, silicate-ester, aliphatics, silicones, fluorocarbons, and the like.

Accordingly, the porous metal layer 310 provides a thermal stress compensation layer between the semiconductor device 300 and the substrate 320, an electrically conductive path between the electrode 335 and the electrode 340, and a thermally conductive cooling layer for the semiconductor device 300.

The preceding description is merely illustrative in nature and is in no way intended to limit the disclosure, its application, or its uses. Work of the presently named inventors, to the extent it may be described in the background section, as well as aspects of the description that may not otherwise qualify as prior art at the time of filing, are neither expressly nor impliedly admitted as prior art against the present technology.

The block diagram in the figures illustrates the functionality and operation of possible implementations of methods and systems according to various forms or variations. In this regard, each block in the block diagram may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

As used herein, the phrase at least one of A, B, and C should be construed to mean a logical (A or B or C), using a non-exclusive logical “or.” It should be understood that the various steps within a method may be executed in different order without altering the principles of the present disclosure. Disclosure of ranges includes disclosure of all ranges and subdivided ranges within the entire range.

The headings (such as “Background” and “Summary”) and sub-headings used herein are intended only for the general organization of topics within the present disclosure and are not intended to limit the disclosure of the technology or any aspect thereof. The recitation of multiple variations or forms having stated features is not intended to exclude other variations or forms having additional features, or other variations or forms incorporating different combinations of the stated features.

As used herein the term “about” when related to numerical values herein refers to known commercial and/or experimental measurement variations or tolerances for the referenced quantity. In some variations, such known commercial and/or experimental measurement tolerances are +/−10% of the measured value, while in other variations such known commercial and/or experimental measurement tolerances are +/−5% of the measured value, while in still other variations such known commercial and/or experimental measurement tolerances are +/−2.5% of the measured value. And in at least one variation, such known commercial and/or experimental measurement tolerances are +/−1% of the measured value.

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . ” as used herein refers to and encompasses any and all possible combinations of one or more of the associated listed items. As an example, the phrase “at least one of A, B, and C” includes A only, B only, C only, or any combination thereof (e.g., AB, AC, BC, or ABC).

As used herein, the terms “comprise” and “include” and their variants are intended to be non-limiting, such that recitation of items in succession or a list is not to the exclusion of other like items that may also be useful in the devices and methods of this technology. Similarly, the terms “can” and “may” and their variants are intended to be non-limiting, such that recitation that a form or variation can or may comprise certain elements or features does not exclude other forms or variations of the present technology that do not contain those elements or features.

The broad teachings of the present disclosure can be implemented in a variety of forms. Therefore, while this disclosure includes particular examples, the true scope of the disclosure should not be so limited since other modifications will become apparent to the skilled practitioner upon a study of the specification and the following claims. Reference herein to one variation, or various variations means that a particular feature, structure, or characteristic described in connection with a form or variation or particular system is included in at least one variation or form. The appearances of the phrase “in one variation” (or variations thereof) are not necessarily referring to the same variation or form. It should also be understood that the various method steps discussed herein do not have to be conducted in the same order as depicted, and not each method step is required in each variation or form.

The foregoing description of the forms and variations has been provided for purposes of illustration and description. It is not intended to be exhaustive or to limit the disclosure. Individual elements or features of a particular form or variation are generally not limited to that particular form or variation, but, where applicable, are interchangeable and can be used in a selected form or variation, even if not specifically shown or described. The same may also be varied in many ways. Such variations should not be regarded as a departure from the disclosure, and all such modifications are intended to be included within the scope of the disclosure.

What is claimed is:

1. A porous metal structure comprising:
a substrate; and
a porous metal layer bonded to the substrate, the porous metal layer comprising a low temperature sintered metal-metal formate slurry layer with less than 10% by volume excess reduced metal formate.

2. The porous metal structure according to claim 1, wherein in the substrate is a semiconductor substrate.

3. The porous metal structure according to claim 2 further comprising a metal layer bonded to the substrate and the porous metal layer bonded to the metal layer.

4. The porous metal structure according to claim 3 further comprising another substrate, wherein the porous metal layer is bonded to the another substrate.

5. The porous metal structure according to claim 4, wherein the another substrate is a cooling substrate and the porous metal layer is sandwiched between the substrate and the another substrate.

6. The porous metal structure according to claim 1, wherein the low temperature sintered metal-metal formate slurry layer, before sintering, comprises a plurality of copper particles mixed with a refined copper formate-solvent solution.

7. The porous metal structure according to claim 6, wherein the plurality of copper particles is a plurality of micron-size copper particles.

8. The porous metal structure according to claim 7, wherein the micron-size copper particles have an average diameter between about 10 micrometers (μm) and about 50 μm.

9. The porous metal structure according to claim 8, wherein a solvent in the refined copper formate solvent solution is isopropanolamine.

10. The porous metal structure according to claim 1 further comprising a power electronics module with a cooling chamber bonded to a semiconductor device, wherein the porous metal layer is disposed within the cooling chamber and bonded to the semiconductor device.

11. The porous metal structure according to claim 10, wherein the porous metal layer comprises a plurality of micro-channels extending from the substrate to an outer surface of the porous metal layer such that a cooling fluid is wicked through the plurality of micro-channels to the substrate.

12. The porous metal structure according to claim 1, wherein the porous metal layer bonded to the substrate has an outer surface comprising an arithmetical mean height less than about 10 μm.

13. A porous metal structure comprising:
a substrate; and
a porous copper layer bonded to the substrate, the porous copper layer comprising a low temperature sintered copper-copper formate slurry layer with less than 10% by volume of excess reduced copper formate and an outer surface with an arithmetical mean height less than about 10 μm.

14. The porous metal structure according to claim 13, wherein in the substrate is a semiconductor substrate, a copper layer is bonded to the substrate, and the porous copper layer is bonded to the copper layer.

15. The porous metal structure according to claim 14, wherein the low temperature sintered copper-copper formate slurry layer, before sintering, comprises a plurality of micron-size copper particles mixed with a refined copper formate-solvent solution.

16. The porous metal structure according to claim 15, wherein the plurality of micron-size copper particles have an average diameter between about 10 micrometers (μm) and about 50 μm.

17. The porous metal structure according to claim 16 further comprising another substrate, wherein the porous copper layer is bonded to the another substrate.

18. The porous metal structure according to claim 17, wherein the another substrate is a cooling substrate and the porous copper layer is sandwiched between the substrate and the cooling substrate.

19. A porous metal structure comprising:
a semiconductor substrate;
a copper layer bonded to the semiconductor substrate; and
a porous copper layer bonded to the copper layer, the porous copper layer comprising a low temperature sintered copper-copper formate slurry layer with less than 10% by volume of excess reduced copper formate and an outer surface with an arithmetical mean height less than about 10 μm.

20. The porous metal structure according to claim 16 further comprising another substrate, wherein the porous copper layer is sandwiched between and bonded to the semiconductor substrate and the another substrate.
